(19) United States
(12) Patent Application Publication
(10) Pub. No.: US 2005/0282300 A1
(43) Pub. Date: Dec. 22, 2005

(54) Back-end-of-line metallization inspection and metrology microscopy system and method using x-ray fluorescence

(75) Inventors: Wenbing Yun, Walnut Creek, CA (US); Yuxin Wang, Arlington Heights, IL (US); Michael Feser, Walnut Creek, CA (US); Kenneth W. Nill, Lexington, MA (US)

Correspondence Address: HOUSTON ELISEEVA, 4 MILITIA DRIVE, SUITE 4, LEXINGTON, MA, 02421, US

(73) Assignee: Xradia, Inc., Concord, CA (US)

(21) Appl. No.: 11/177,227

(22) Filed: Jul. 8, 2005

Related U.S. Application Data
(63) Continuation-in-part of application No. 10/157,089, filed on May 29, 2002.
(60) Provisional application No. 60/586,835, filed on Jul. 9, 2004.

(51) Int. Cl. G01R 31/26; G06F 19/00; H01L 21/44; H01L 21/66

(52) U.S. Cl. 438/14; 438/687; 700/121

(57) ABSTRACT

Systems and methods for performing inspection and metrology operations on metallization processes such as on back-end-of-line (BEOL) metallization thickness and step coverage are disclosed. Specific examples include measurements of thickness and uniformity of barrier layers, including tantalum for example, and seed layers, including copper for example, in Damascene, including dual-Damascene, trenches during the interconnect fabrication steps of integrated circuit production. The invention also relates to the detection and measurement of void formation during and after copper electroplating. The invention utilizes x-ray fluorescence to measure the absolute thicknesses and the thickness uniformity of the barrier layers in the trenches, the copper seed layers for electroplating, and the final copper interconnects.

### RELATED APPLICATIONS

This application claims the benefit under 35 USC 119(e) of Provisional Application No. 60/586,835, filed Jul. 9, 2004, which is incorporated herein by reference in its entirety.

This application is a Continuation-in-Part of U.S. application Ser. No. 10/157,089 filed on May 29, 2002, which is incorporated herein by reference in its entirety.

### BACKGROUND OF THE INVENTION

The conductive layers or interconnects in semiconductor devices are usually formed from aluminum, gold, or tungsten. Recently, efforts have been focused on migrating to copper, however. Copper conducts electricity with about one half the resistance of aluminum. This can be directly translated into increases in the speed of microprocessors that use copper conductors in place of aluminum. Also, at high current densities, copper is far less vulnerable than aluminum to electromigration, which is the movement of individual atoms through a conductor, caused by high electric currents. This process can lead to the creation of voids and ultimately breaks in the conductor traces.

A major challenge in using copper for interconnects relates to its chemical properties. It will readily diffuse into silicon, changing the electrical properties of silicon in such a way as to prevent transistors that are formed in the silicon from functioning properly.

The copper diffusion problem is typically addressed by using combinations of thin barrier layers and electroplating, which requires the deposition of thin seed layers. While thin, these layers must also be uniform and unbroken especially in the regions in which the traces of the interconnects are to be formed.

One standard process for fabricating the copper interconnects in semiconductor industries is often referred to as the Damascene process. It starts with the substrate of silicon oxide (SiO₂) or low-k dielectric materials that have been deposited or grown on a silicon wafer substrate. Trenches are then fabricated for the interconnects using a lithographic process. Into and around the trenches, a thin layer of diffusion barrier material is then deposited. Typically, this barrier material is titanium (Ti), tantalum (Ta), tantalum nitride (TaN), or tantalum silicon nitride (TaSiN), which has been deposited with chemical vapor deposition (CVD). The thickness of this barrier layer is typically between 1 and 5 nanometers (nm), and serves to prevent the subsequently-deposited copper from diffusing into the substrate. To deposit the copper, a thin layer of copper is first deposited on top of the barrier layer. This thin layer is used to establish electrical connections for the formation of the copper interconnects by electroplating. The thickness of this seed layer is usually between 1 and 5 nm.

The proper formation of the barrier and the seed layers is critical in the fabrication process. Many common circuit failures result from defects during the deposition of these two layers. For example, non-uniformity in the barrier and seed layers can cause the trench to close prematurely during the electroplating process. This will yield an interconnect trace that has a high electrical resistance. A void or gap in the barrier layer can lead to diffusion of the copper from the interconnect into the substrate layers. This process can result in an open circuit when the copper is reduced or depleted, or a short circuit to neighboring traces or lines in the context of the interconnect and adversely affect the doping and thus electrical properties of the underlying silicon.

### SUMMARY OF THE INVENTION

The present invention relates to systems and methods for performing inspection and metrology operations on metallization processes such as on back-end-of-line (BEOL) metallization thickness and step coverage. Specific examples include measurements of thickness and uniformity of barrier layers, including tantalum for example, and seed layers, including copper for example, in Damascene, including dual-Damascene, trenches during the interconnect fabrication steps of integrated circuit production. The invention also relates to the detection and measurement of void formation during and after copper electroplating. The invention utilizes x-ray fluorescence to measure the absolute thicknesses and the thickness uniformity of the barrier layers in the trenches, the copper seed layers for electroplating, and the final copper interconnects.

In general according to one aspect, the invention features a system for analyzing trenches in copper interconnect fabrication in semiconductor devices. The system comprises an excitation source for generating excitation radiation to induce generation of x ray fluorescence radiation from the material layers in or around the trenches and a detector for detecting the fluorescence radiation.

In general according to one aspect, the invention features a method for analyzing trenches in copper interconnect fabrication in semiconductor devices. The method comprises generating excitation radiation to induce x ray fluorescence radiation from material layers in or around the trenches and detecting the fluorescence radiation.

In general according to another one aspect, the invention features a method for analyzing diffusion barrier or interlayer dielectric layers in semiconductor devices, This method comprises generating radiation to induce x ray fluorescence radiation from the diffusion barrier or interlayer dielectric layers and detecting the fluorescence radiation.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is a schematic view of a fluorescence analysis system for inspection and metrology of the barrier layers, seed layers, and final copper interconnect layers in a Damascene process;

FIG. 2 shows a Fresnel zone plate lens;

FIGS. 3A and 3B are cross-sectional schematic views illustrating the formation of copper interconnects using the Damascene process used in the formation of metallization such as copper interconnects;

FIGS. 4A and 4B are cross-sectional views of the Damascene trenches illustrating defects in the layer deposition;

FIGS. 5 and 6 are schematic side views illustrating the use of the fluorescence analysis system to survey trench sidewalls;

FIG. 7 is schematic side view illustrating the use of the fluorescence analysis system to survey trench floors;

FIG. 8 is schematic side view illustrating the use of the fluorescence analysis system to analyze copper interconnects for voids;

FIG. 9 is schematic side view illustrating a multi detector fluorescence analysis system.

### DETAILED DESCRIPTION OF THE PREFERRED EMBODIMENTS

The preferred embodiment of the invention concerns an x-ray fluorescence metallization analysis system for the inspection and metrology of the barrier and seed layers for metallization processes such as during and after Damascene processes. It also concerns the detection, measurement and other characterization of void formation during or after the deposition, such as by electroplating, of interconnect structures, such as interconnects formed from copper.

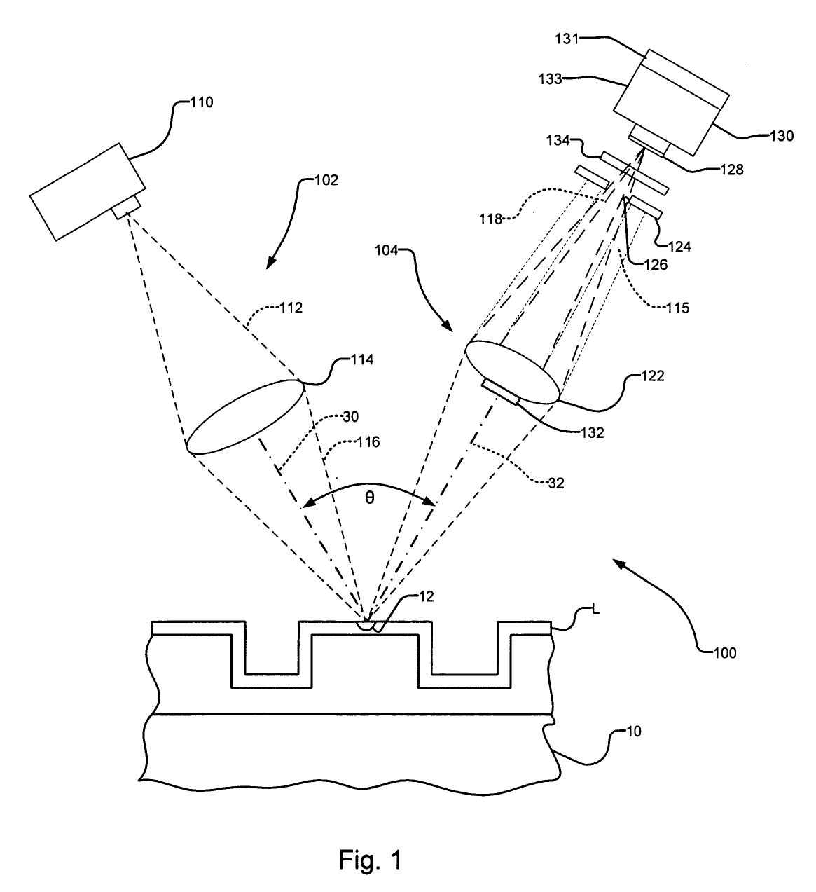

FIG. 1 illustrates an x-ray metallization analysis system 100 that has been constructed according to the principles of the present invention.

The system 100 comprises an excitation system 102 that has an excitation source 110. This excitation source 110 generates a radiation beam that is used to generate the x-ray fluorescence emissions from the sample or device under analysis 10.

Typically, the excitation radiation 112 is either x-ray radiation or an electron beam. The electron sources include thermionic sources and field-emission sources. Practical focused electron excitation spot sizes are in the range of 1 micrometer (μm) to 1 millimeter (mm). Finer beam sizes with 1 μm to 1 nm can also be used. They are typically scanned across the field of view of the x-ray imaging system. Practical examples of electron sources include electron guns, scanning electron microscopes, and electron-probes and microprobes used for surface science. Typical x-ray sources include electron-bombardment sources (including rotating anode, micro-focus, and tube sources), gas-discharge sources, laser-plasma sources, and synchrotron radiation sources. Typical targets for an electron-bombardment source include tungsten (W), copper (Cu), chromium (Cr), and molybdenum (Mo).

Most elements of interest here have emission lines within the range of 0.2-5 kiloelectron-Volts (keV). To effectively induce fluorescence emission, electron or x-ray beams with energies between 2 and 20 keV are generally required. For example, with current semiconductor manufacturing technology, the analysis of tantalum (Ta) of the barrier layer and copper (Cu) of the seed layer is critical. Their emission wavelengths are 7.25 Å (1.71 keV) and 13.3 Å (0.93 keV), respectively.

More generally, with electrons, the energy has to be above the emission energy of the element of interest. The optimal energy for maximum fluorescence production is about 3 times the emission energy. This gives the most characteristic emission compared with the Bremsstrahlung background emission. For example, with copper L line at 900 electron-Volts (eV), the optimal excitation energy is about 3 keV. This energy also provides good penetration. There is an empirical formula for the approximate probing depth: 0.077*Energy^{3/2}/density, [Energy]=keV, and [density]=g/cm³. Thus, a range of 1-50 keV would be practical for most applications.

The excitation beam 112 is preferably focused onto the sample 10 with a lensing device 114 to create converging beam 116.

If the excitation radiation 112 is an electron beam, then the lensing device 114 is preferably an electronic and magnetic. For example, electrostatic or magnetic optics are often used to focus the electrons to a small spot 12 by generating the focused beam 116 that converges on the sample 110.

In the case where the excitation beam 112 is x ray radiation, then the lensing device is a x ray condenser or focusing lens, such as a zone plate lens, (compound) refractive lens, or reflective lens (including capillary or mirror-optics).

In one example, the x-ray lensing device 114 is a capillary condenser as described in U.S. patent application Ser. No. 10/704,381 to Yun, et al., filed Nov. 7, 2003, entitled, “X-ray Microscope Capillary Condenser System,” which application is incorporated herein by this reference in its entirety.

Alternatively, the x-ray target of the source 110 is placed in proximity to the sample 10 to eliminate the need for an x ray lensing device 114.

Whether electron or x-ray excitation beams 112 are used, the excitation spot size 12 on the sample 10 must preferably be kept small. Generally, its size should be limited to 1 to 50 μm or smaller. The beam spot affects the spectral resolution. As a rule of thumb, the spectral bandwidth is about the size of the beam divided by the diameter of the objective lens.

According to one application, the spot 12 is located on a thin metal layer L, such as a tantalum barrier layer or a copper seed layer L of the sample 10. Generally, the system 100 is most relevant to metal thin layers of having a thickness of less than 100 nm and usually less than 20 nm, and even less than 10 nm.

In other examples, x ray fluorescence radiation is induced from interlayer dielectric layers.

The illuminated spot 12 produces x-ray emissions with specific wavelengths that are characteristic of the elemental composition of the layer L. A few emission wavelengths for elements of interest are as follows:

| Element | Line | Wavelength (Å) | Energy (keV ) |
|---|---|---|---|
| Si | K | 7.13 | 1.74 |
| Ta | M | 7.25 | 1.71 |
| N | K | 31.6 | 0.39 |
| Cu | L | 13.3 | 0.93 |
| W | M | 6.98 | 1.78 |
| O | K | 23.6 | 0.525 |
| Al | K | 8.34 | 1.49 |

The induced secondary or x-ray fluorescence emission 120 is then imaged onto a detector 130 of a detector system 104 in the preferred embodiment. An x ray objective lens 122 is preferably used to image this fluorescence emission 120.

In the preferred embodiment, the x-ray stage of the detector system 104 provides for magnification of the image to improve resolution. Specifically, the distances between the sample 10, the objective 122 and the detector 130 are such that there is magnification. Preferably, the magnification power is greater than 1.0 or preferably greater than 1.5 to 2 magnification to as high and 500 or more.

Preferably, the detector 130 comprises a detector element 131 such as a charged coupled device (CCD) chip or camera. It also preferably comprises an optical magnification stage 133 in one embodiment. Specifically, the x-rays are imaged onto a scintillator 128 that converts the x-rays into light. The detector 130 then further magnifies the optical signal generated by the scintillator in optical stage 133, such as a microscopy objective/tube lens system, which then images that optical signal on detector element 131.

In some embodiments, a back-illuminated CCD camera can be used to detect the x rays directly. The typical pixel sizes of the CCD camera are 5-30 μm. The magnification of the imaging system is simply ratio of the CCD pixel size and the intended pixel size on the sample. For example, to achieve 50 nm imaging resolution, a 25 nm sample pixel size is needed to satisfy the Nyquist principle. If a CCD camera with 13 μm pixel size is used, a magnification of at least 520 is required in the x ray stage. With this setup, if the zone plate has a focal length of 1 mm, the total optical path is about 521 mm.

Alternatively, a CCD camera can also be used in conjunction with a scintillator screen and various types of optical coupling including microscope objective and optical fiber taper. This can reduce the magnification at the x-ray stage and consequently the size of the system. With the same example as above, if the microscope objective has a magnification of 20, the x-ray system only needs a magnification of 26 and the x-ray beam path can be reduced to 27 mm.

When used to collect the total fluorescence signal from a uniform area, a single element detector such as photon counting module, PIN diode, can be used. This system is well suited for measuring the uniformity of thin films.

In one example, the optical stage is configured as disclosed in U.S. patent application Ser. No. 10/704,382 by Yun, et al., filed on Nov. 7, 2003 entitled, Scintillator Optical System and Method of Manufacture,” which is incorporated here in its entirety by this reference.

A suitable zone plate objective 122 will have a diameter between 10 μm and 1 mm and outer most zone width of less than 50 nm. It is typically fabricated from various materials including, but not limited to gold (Au), copper (Cu), tantalum (Ta), molybdenum (Mo), and nickel (Ni).

A central stop 132 on the zone plate and an aperture plate 124 near the detector 130 are used in tandem to select the desired wavelength. The central stop 132 and the aperture 126 of the aperture plate 124 typically have similar size of 25% to 75% of the diameter of the zone plate 122. The central stop 132 improves signal to noise ratio by blocking x rays that are not diffracted by the zone plate.

A monochromator or spectral filter 134 is also used in some cases. It is placed between the sample 10 and detector 130 in the optical path to further increase the energy resolution and improve the sensitivity to a certain material by filtering out or attenuating x rays other than a x rays of the desired energy from the element of interest. The filter is arranged in either a reflection geometry or transmission geometry (shown).

Nonetheless, the system 100 inherently provides some energy selectivity. As a diffractive optical element, the zone plate 122 is strongly chromatic. Consequently, in addition to forming the image from the x-ray emission 120 on the detector 130 for x-rays of the desired energy, the zone plate 122 also separates the spectrum by imaging x-ray radiation with different energies to different longitudinal distances. For example, if the sample 10, zone plate 122, and the detector 130 are arranged to focus the Cu emission at 13.3 Å, emission from the same sample area with other energies will be out of focus or rejected with proper aperturing. In the current embodiment, the aperturing is performed by the pinhole aperture plate 124.

The aperture plate 124 comprises a pinhole aperture 126 that is sized to allow for the passage of the converging beam 118 that corresponds to the x-rays of the desired energy. Specifically, these are the energies that result from the fluorescence of the element of interest. Higher energy x-rays 115 are still converged by the objective 122. The x-ray objective, however, is not as efficient for these higher energy x-rays 115. They are thus stopped by the solid portion of the aperture plate 124.

The angle θ between the optical axis 30 of the excitation beam 116 and optical axis 32 of the detection system 104 is preferably small. Generally, practical values for angle θ are between 0 and 60 degrees. However, in many applications, such as analyzing Damascene trenches, smaller angles are required, such that angle θ is less than 15 degrees. For example, the trenches have high aspect ratios, about 10:1 at some lower level interconnects. That constrains the imaging angle to less than 10 degrees or about 6 degrees, or less. In one preferred embodiment, the excitation optical axis 30 and the detection optical axis 32 are coaxial and normal to the surface of the sample 10. Ideally, at least the detection optical axis 32 should be normal to the surface of the sample 10 in order to keep the sample area in focus since when tilted, the region of interest will have different focal distance to the lens. So there is a need to minimize the angle offset with instrumentation design.

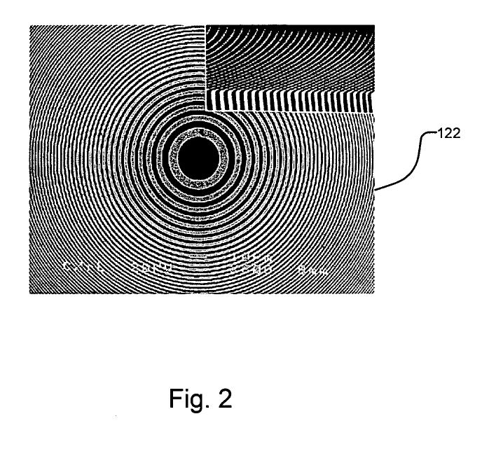

FIG. 2 shows an exemplary zone plate objective lens 122. It is a diffractive imaging optic having a set of concentric rings with the ring (zone) width decreasing with radii defined by
rₙ²=nλf_{z}+an²λ², (1)

where n is the zone number index, and f_{z} is the focal length, and a=0.25 for imaging an object at infinity or at large magnification.

In one version, these rings alternate between transparent and an opaque materials. This way, the opaque rings block light that would arrive at the focal point out of phase with respect to the light passing through the transparent areas. Such zone plates, called amplitude zone plates, have a maximum theoretical efficiency of about 10%.

Instead of opaque rings, a phase shifting material is used in other versions. The material thickness is selected to shift the phase of the light by π. This results in a phase zone plate, with maximum theoretical efficiency of about 40%.

The amplitude and phase zone plate are both binary zone plates because of their binary zone profile. Alternatively, the square profile of a phase zone plate can be replaced by a graduated one that shifts the exact phase error at each point on the lens. The resulting blazed zone plate, which is an extreme case of a Fresnel lens, has a maximum theoretical efficiency of 100%.

Zone plates behave like lenses with a focal length of

$${f}_{Z} = \frac{2 R Δ R}{λ} , \qquad ( 2 )$$

where 2R is the diameter of the zone plate and ΔR is the width of the finest, outermost zone. The resolution measured by the Rayleigh criteria is 1.22ΔR, slightly higher than the outer zone width. In practice, zone widths as small as ΔR=20 nm have been fabricated for λ=2-5 nm x-ray radiation, delivering better than 25 nm resolution, while zone widths of ΔR=40 nm have been used for shorter wavelength (λ<0.5 nm) radiation. Therefore the disclosed system is able achieve resolutions at the level of tens of nanometers.

The numerical aperture of a zone plate can be easily derived from diffraction theory as:
NA=λ/2ΔR (3)

This is usually a very small number. For example, when a zone plate with 30 nm outer zone width is used image copper emission of 1.33 nm wavelength, the resulting numerical aperture is 0.022, or a full cone angle of 2.5 degrees. Therefore, the beam imaged by the zone plates is a sharp “pencil beam”. The important advantage of this property is that it can be used to probe into very narrow openings such as tall trenches with very high aspect ratios.

Since a zone plate focuses with its diffractive properties, the diffraction angle and consequently the focusing strength depends strongly on the wavelength. This means that a zone plate is highly chromatic and number of zones N determines the required illumination monochromaticity, or spectral bandwidth:

$$\frac{N}{2} = \frac{R}{4 Δ R} = \frac{λ}{Δ λ} . \qquad ( 4 )$$

The chromatic aberration is generally a negative attribute for applications with a broad-band x-ray spectrum. One can, however, take advantage of this property to independently image radiation of different wavelengths. In effect, the zone plate 122 can be made to simultaneously perform an imaging and spectral filtering function. The simultaneous imaging and spectral filtering capabilities makes the system 100 a powerful tool in a number of applications where high-resolution and elemental-specific imaging is desired.

In a first application, the system 100 is used to measure the absolute thickness of a thin metal film L (e.g. the barrier layer or the Cu seed layer) by recording the total fluorescence signal from a sample region. This is application takes advantage of the property that under a fixed excitation beam, the fluorescence emission from an area of thin film is proportional to the volume. Hence the thickness of the thin film can be obtained by measuring its fluorescence emission and calibrating against a standard film with known thickness. Here, the full-field image formed by the lens provides a direct measurement of the thickness of each pixel area and the thickness uniformity can be directly obtained.

In addition to thin film on top of a planar structure, the system described here can also make the measurement in the bottom of the Damascene trench by focusing in this area. Furthermore, side wall of trench can also be measured by tilting the measurement system. With this approach, a trench with aspect ratio (depth-to-width) of 1-10 is can be effectively measured.

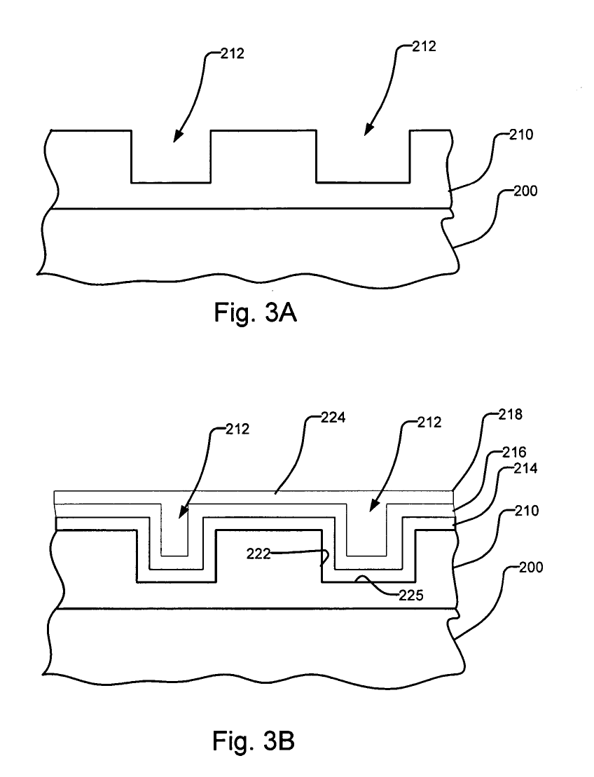

FIGS. 3A and 3B illustrate the Damascene metallization process for depositing copper interconnects illustrating one application for the present invention.

Specifically, as illustrated in FIG. 3A, in one example of a Damascene process, a patterned silicon oxide layer 210 is formed or deposited on a silicon wafer substrate 200. In one example, the silicon oxide layer 210 is grown on the silicon substrate 210. Then in a lithography patterning step, a photo resist is deposited and patterned to expose regions of the silicon oxide 210 to a directional etch process to thereby form the trenches 212.

As illustrated in FIG. 3B, a barrier layer 214 is next preferably deposited over the silicon oxide layer 210 into the trenches 212. Typically, this is a conformal coating process to ensure that both the trench bottoms 225 and the trench sidewalls 222 are coated with the thin barrier layer 214, which in one example is tantalum.

After the deposition of the tantalum, barrier layer 214, a thin copper seed layer 216 is deposited. In one example, this is a conformal coating, but in other examples the seed layer is deposited primarily in the bottoms 225 of the trenches 212. Thereafter, the final thick copper layer 218 is formed over the substrate, via electroplating in one example. The portions of the copper layer that lies between the trenches (see reference 224) can be removed in an etching or chemical-mechanical polishing (CMP) step.

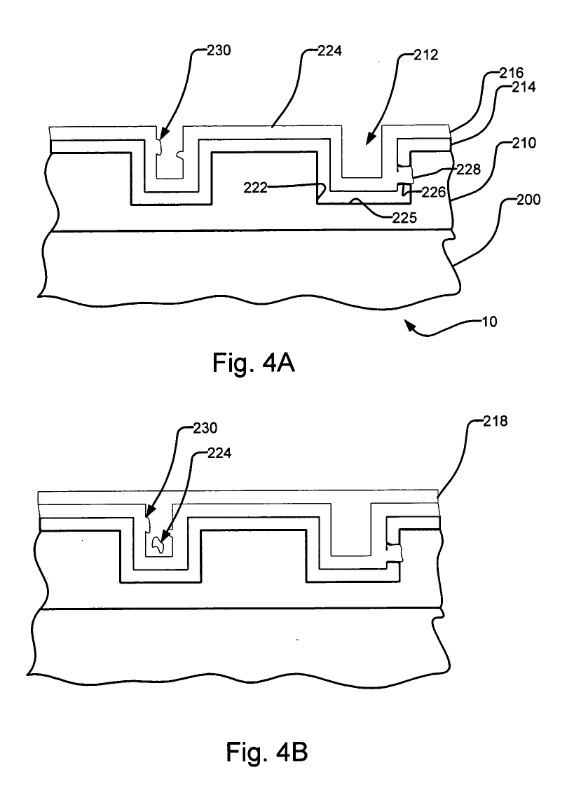

FIGS. 4A and 4B illustrate how defects in the formation of the barrier and seed layers 214, 216 lead to defects in the formation of the interconnects or integrated circuits and thus improper operation of the semiconductor devices formed in this manner.

As illustrated in FIG. 4A, areas of nonuniformity in the deposition of the seed layer 216, such as nonuniformities 230, give rise to bumps or inconsistencies in the sidewalls 222 in the trenches 212. Such inconsistencies can also arise from nonuniforminties in the formation of the barrier layer.

As illustrated in FIG. 4B, these nonuniformities 230 lead to the formation of voids 224 during the subsequent plating process in which the copper of the interconnects is plated into the trenches 212. Part of this results from characteristics of the plating process. Often nonuniformities 230 will preferentially receive material in the plating process due to diffusion of the copper in the plating bath and the complex distribution of the electric fields in the trenches 212. This can result in the formation of voids, such as 224, which create local increases in the resistance of the interconnect during operation. This can result in excessive heating, and/or other improper operation of the semiconductor device.

Another type of defect occurs in areas of poor coverage in the barrier layer 216. In the illustrated example, there is a gap 226 in the coverage on the sidewall 222. As a result, the subsequent copper seed layer 216 is in direct contact 228 with the silicon oxide layer 210 and possibly the silicon substrate 220 depending on the particular process used. As a result, copper atoms from the seed layer 216 and from the interconnect layer 218 are able to diffuse into the silicon oxide layer 210 and/or also the substrate 220. This changes the doping concentration in the transistors formed in the substrate 200, for example, which can cause these transistors to not function properly.

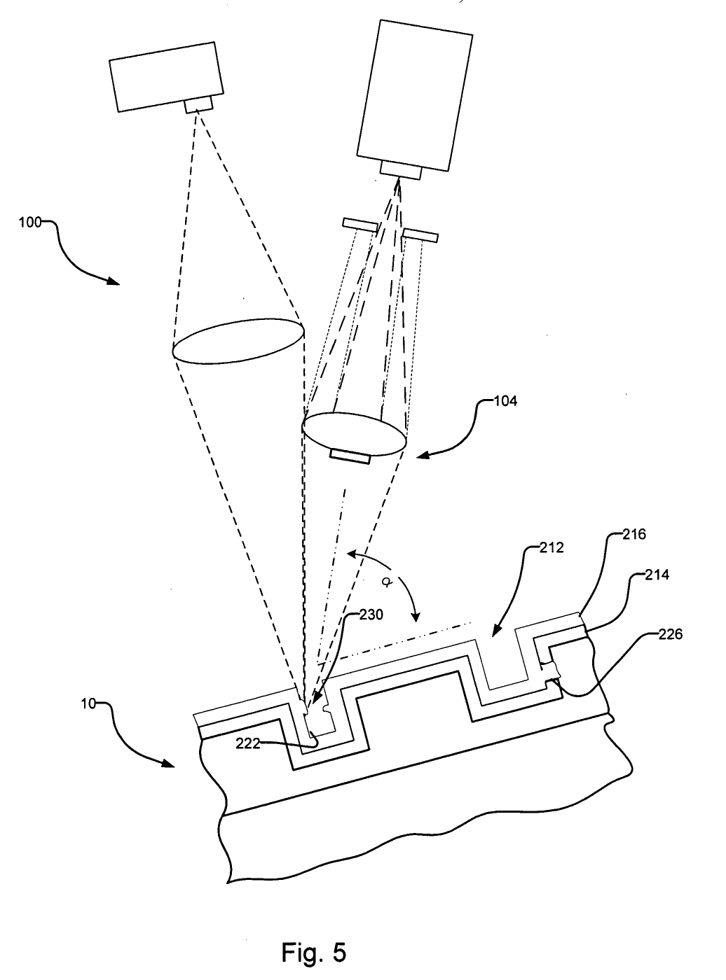

As illustrated in FIG. 5, the imaging system can be used to detect nonuniformities in the deposition of the area and the seed layers 214, 216. In an illustrated example, the imaging system 100 is used to image the side walls 222 to locate uniformities 230. This is achieved by rotating the imaging system relative to the sample. In one example, the angle α between the sample and the detection system 104 of the analysis system 100 is near perpendicular in order analyze the entire side wall 222. For example, the angle α is greater than 70 degrees but less than about 85 degrees.

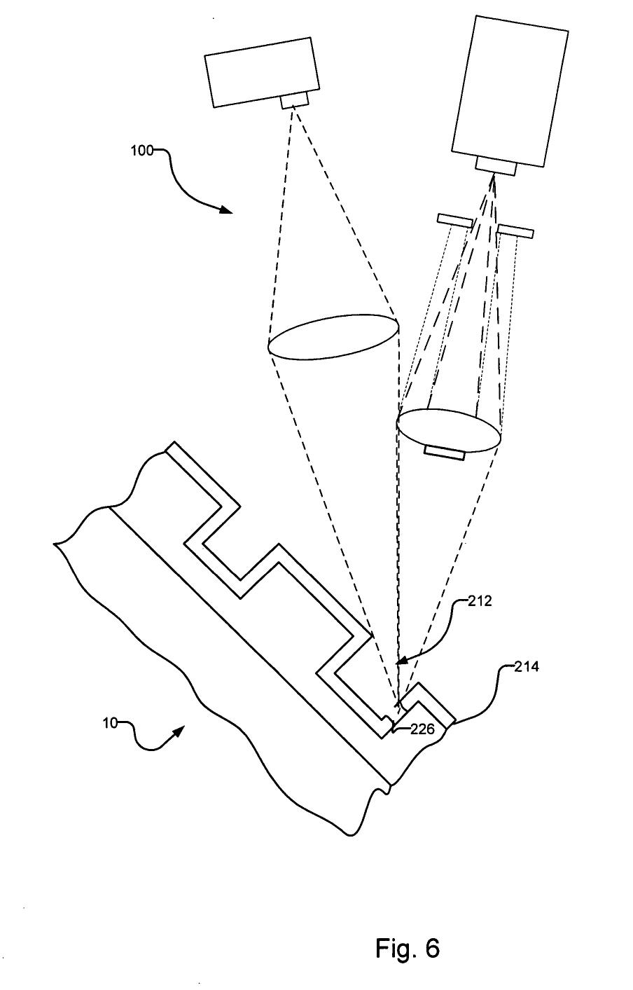

As illustrated in FIG. 6, the imaging system 100 can also be used to find gaps 226 in the barrier layer 214. In this example, the imaging condition is set to image the emission lines of the material of the barrier layer 214.

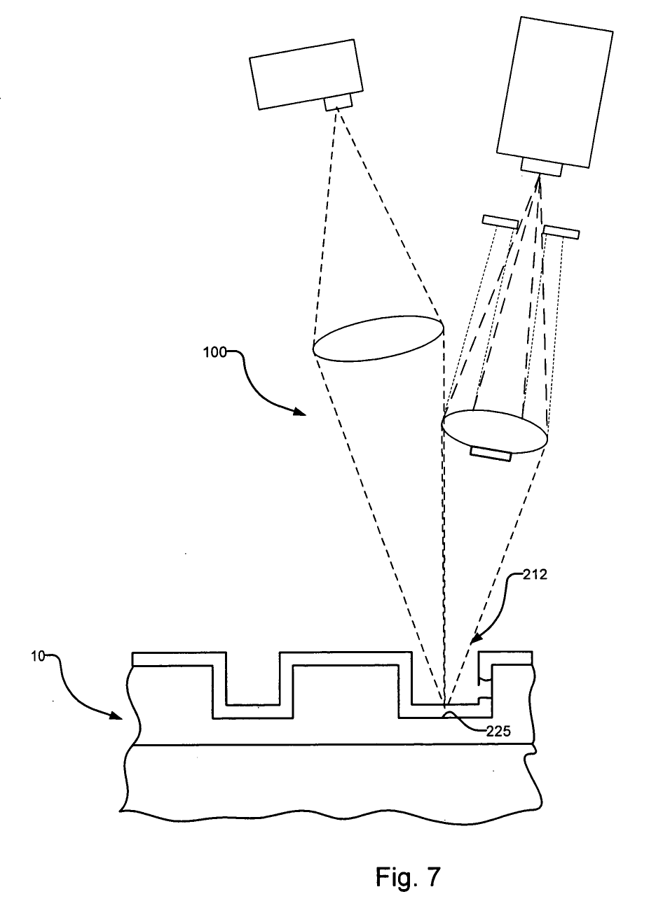

As illustrated in FIG. 7, the imaging system can also be used to detect and characterize the bottoms 220 of the trenches 212.

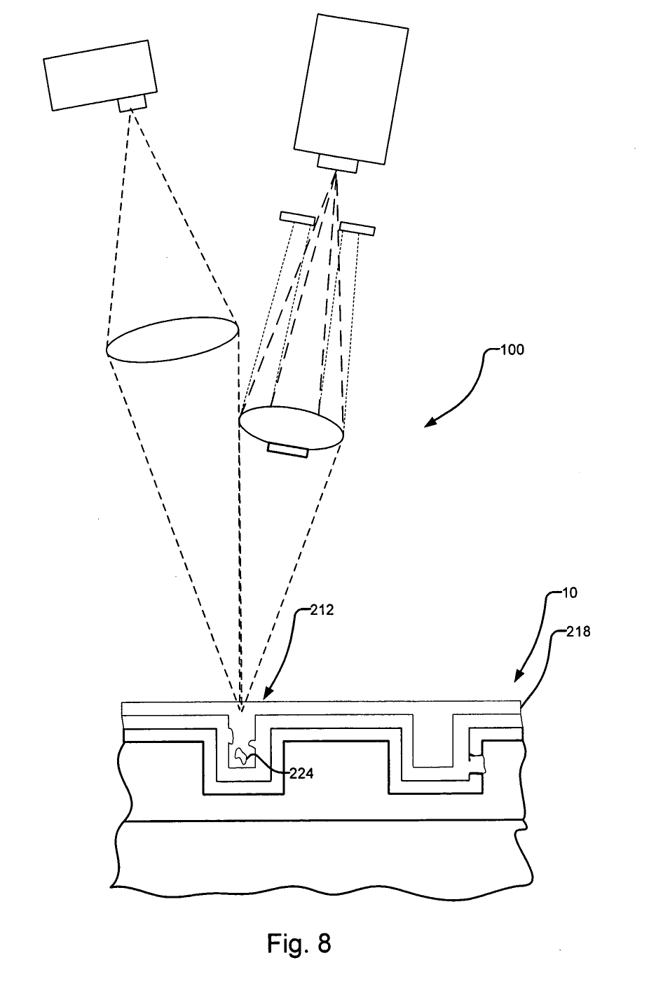

The another application of the analysis system 100 is the detection, measurement and characterization of voids 224 formed in copper structures during and after the electroplating process by directly imaging it in the circuit structure. An embodiment is shown in FIG. 8 where an electron or x-ray excitation source is used to generate fluorescence emission from the IC structures. The fluorescence emission is imaged by the detection system. Within a thin layer of the sample of up to 1 μm, the fluorescence signal detected by each pixels of the imaging system is approximately proportional to the volume of the material emitting the radiation with the designed wavelength. Therefore, a void in the circuit structure can be visualized as a local signal loss and the size and shape of the void can be determined from the signal level and the intensity distribution of the fluorescence image.

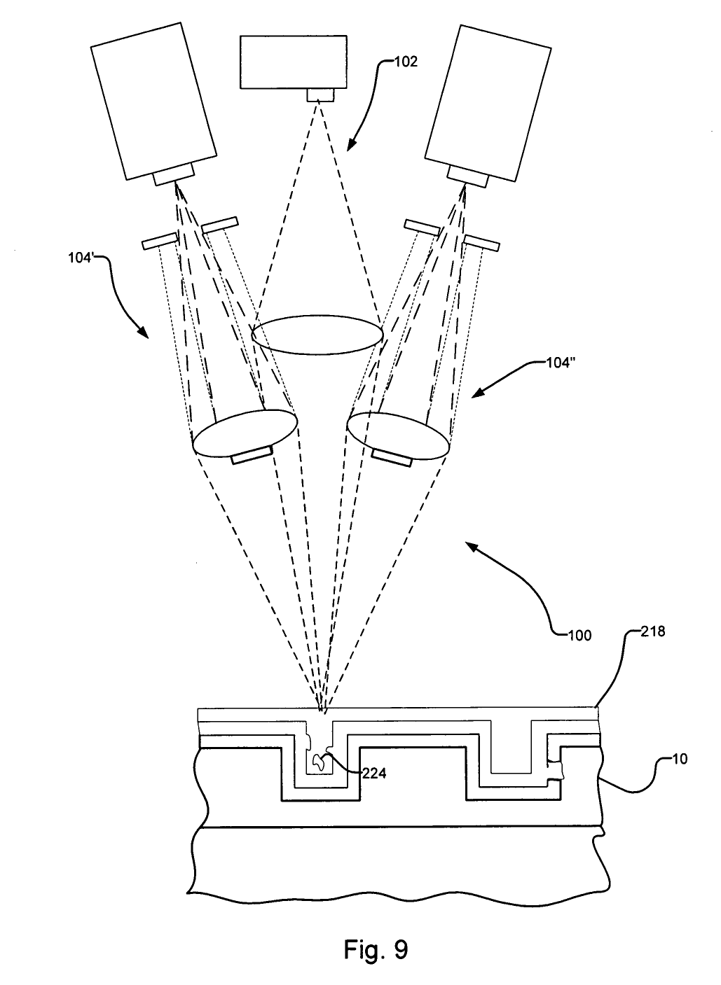

Another embodiment is shown in FIG. 9, two detection systems 104′, 104″ are arranged at different angles. The two resulting images can be used to determine the 3D location and shape of the void by stereo imaging methods. Additional detection systems can be employed to improve the 3D image fidelity. An extreme case is when a large number of detector are used in a tomographic imaging or laminography imaging setup. Alternatively, instead of using multiple detectors, a single detector can also be scanned across a number of angles in both the polar and azimuthal directions, to obtain the projection data. This method provides a tradeoff of throughput for cost.

While this invention has been particularly shown and described with references to preferred embodiments thereof, it will be understood by those skilled in the art that various changes in form and details may be made therein without departing from the scope of the invention encompassed by the appended claims.

1. A system for analyzing trenches in copper interconnect fabrication in semiconductor devices, the system comprising:
an excitation source for generating excitation radiation to induce generation of x ray fluorescence radiation from the material layers in or around the trenches;
a detector for detecting the fluorescence radiation.

2. A system as claimed in claim 1, wherein the excitation source generates electron beam radiation to induce the generation of the x ray fluorescence radiation.

3. A system as claimed in claim 1, wherein the excitation source is an electron source of a scanning electron microscope.

4. A system as claimed in claim 1, further comprising a lens for imaging the x ray fluorescence radiation onto the detector.

5. A system as claimed in claim 4, wherein the lens is a chromatic lens.

6. A system as claimed in claim 4, wherein the lens is a zone plate lens.

7. A system as claimed in claim 6, further comprising a pupil aperture for improving preferential imaging of the secondary radiation.

8. A system as claimed in claim 7, further comprising a central stop to attenuate x rays not focused by the zone plate lens.

9. A system as claimed in claim 4, further comprising a central stop to attenuate x rays not focused by the lens.

10. A system as claimed in claim 9, wherein the central stop is located on the lens.

11. A system as claimed in claim 1, further comprising a spectral filter for reducing radiation other than the x ray fluorescence radiation from the material layers from reaching the detector.

12. A system as claimed in claim 11, wherein the spectral filter is a multilayer optic operating in either a reflection geometry or transmission geometry.

13. A system as claimed in claim 11, wherein the spectral filter is a crystal.

14. A system as claimed in claim 1, wherein the detector comprises a two dimensional array of detector elements to provide two dimensional spatial resolution.

15. A system as claimed in claim 14, wherein the detector elements charge coupled devices optimized for direct detection of x-rays.

16. A system as claimed in claim 14, wherein the detector comprises a scintillator and an optical imaging system for imaging light from the scintillator onto the array of detector elements.

17. A system as claimed in claim 1, wherein the system measures the thickness and thickness uniformity of a barrier layer and/or the copper seed layer in a Damascene process, including the bottom and the sidewalls of the trench.

18. A system as claimed in claim 1, wherein the system has multiple detectors arranged at different angles, and use images from these detectors to reconstruct the three-dimensional location and shape of voids in the material layers.

19. A system as claimed in claim 1, wherein the system has multiple detectors arranged at different angles, and uses images from these detectors to reconstruct the three-dimensional location and shape of the voids with laminography or tomography methods.

20. A system as claimed in claim 1, wherein an angle θ between an optical axis of the excitation radiation and the fluorescence radiation detected by the detector is between 0 and 60 degrees.

21. A system as claimed in claim 1, wherein an angle θ between an optical axis of the excitation radiation and the fluorescence radiation detected by the detector is less than 15 degrees.

22. A system as claimed in claim 1, wherein an angle θ between an optical axis of the excitation radiation and the fluorescence radiation detected by the detector is less than 10 degrees.

23. A system as claimed in claim 1, wherein an angle α between a surface of a sample and an optical axis of the detected fluorescence radiation is greater than 70 degrees but less than about 85 degrees.

24. A method for analyzing trenches in copper interconnect fabrication in semiconductor devices, the method comprising:
generating excitation radiation to induce x ray fluorescence radiation from material layers in or around the trenches; and
detecting the fluorescence radiation.

25. A method as claimed in claim 24, wherein the step of generating the radiation comprises generating an electron beam to induce generation of the x ray fluorescence radiation.

26. A method as claimed in claim 24, wherein the step of detecting the fluorescence radiation comprises focusing the fluorescence radiation.

27. A method as claimed in claim 26, wherein fluorescence radiation is focused with a zone plate lens.

28. A method as claimed in claim 27, further comprising filtering radiation with a pupil aperture.

29. A method as claimed in, claim 28, further comprising filtering x rays not focused by the zone plate lens.

30. A method as claimed in claim 24, wherein the step of detecting the fluorescence radiation comprises imaging the fluorescence radiation onto a two dimensional array of detector elements.

31. A method as claimed in claim 24, further comprising determining a thickness of the material layers.

32. A method as claimed in claim 24, further comprising measuring the thickness and thickness uniformity of a barrier layer and/or the copper seed layer.

33. A method as claimed in claim 24, further comprising using multiple detectors arranged at different angles, and using images from these detectors to reconstruct the three-dimensional location and shape of voids in the material layers.

34. A method as claimed in claim 24, wherein an angle θ between an optical axis of the excitation radiation and the detected fluorescence radiation is between 0 and 60 degrees.

35. A method as claimed in claim 24, wherein an angle θ between an optical axis of the excitation radiation and the detected fluorescence radiation is less than 15 degrees.

36. A method as claimed in claim 24, wherein an angle α between a surface of a sample and an optical axis of the detected fluorescence radiation is greater than 70 degrees but less than about 85 degrees.

37. A method for analyzing diffusion barrier or interlayer dielectric layers in semiconductor devices, the method comprising:
generating radiation to induce x ray fluorescence radiation from the diffusion barrier or interlayer dielectric layers; and
detecting the fluorescence radiation.

38. A method as claimed in claim 37, wherein the step of generating the radiation comprises generating an electron beam to induce generation of the x ray fluorescence radiation.

39. A method as claimed in claim 37, wherein the step of detecting the fluorescence radiation comprises focusing the fluorescence radiation with a zone plate lens.

40. A method as claimed in claim 37, further comprising determining a thickness of the diffusion barrier or interlayer dielectric layers.

41. A system for analyzing copper interconnects in semiconductor devices, the system comprising:
an excitation source for generating radiation to induce generation of x ray fluorescence radiation from the copper interconnects;
a detector for detecting the fluorescence radiation.

42. A system as claimed in claim 41, wherein the excitation source generates electron beam radiation to induce the generation of the x ray fluorescence radiation.

43. A system as claimed in claim 41, wherein the excitation source is an electron source of a scanning electron microscope.

44. A system as claimed in claim 41, further comprising a lens for imaging the x ray fluorescence radiation onto the detector.

45. A system as claimed in claim 44, wherein the lens is a chromatic lens.

46. A system as claimed in claim 44, wherein the lens is a zone plate lens.

47. A system as claimed in claim 46, further comprising a pupil aperture for improving preferential imaging of the secondary radiation.

48. A system as claimed in claim 47, further comprising a central stop to attenuate x rays not focused by the zone plate lens.

49. A system as claimed in claim 44, further comprising a central stop to attenuate x rays not focused by the lens.

50. A system as claimed in claim 49, wherein the central stop is located on the lens.

51. A system as claimed in claim 41, further comprising a spectral filter for blocking radiation other than the x ray fluorescence radiation from the copper interconnects from reaching the detector.

52. A system as claimed in claim 51, wherein the spectral filter is a multilayer optic.

53. A system as claimed in claim 51, wherein the spectral filter is a crystal.

54. A system as claimed in claim 41, wherein the detector comprises a two dimensional array of detector elements to provide two dimensional spatial resolution.

55. A method for analyzing copper interconnects in semiconductor devices, the method comprising:
generating radiation to induce x ray fluorescence radiation from the copper interconnects;
detecting the fluorescence radiation.

56. A method as claimed in claim 55, wherein the step of generating the radiation comprises generating an electron beam to induce generation of the x ray fluorescence radiation.

57. A method as claimed in claim 55, wherein the step of detecting the fluorescence radiation comprises focusing the fluorescence radiation.

58. A method as claimed in claim 57, wherein fluorescence radiation is focused with a zone plate lens.

59. A method as claimed in claim 58, further comprising filtering radiation with a pupil aperture.

60. A method as claimed in claim 58, further comprising filtering x rays not focused by the zone plate lens.

61. A method as claimed in claim 55, wherein the step of detecting the fluorescence radiation comprises imaging the fluorescence radiation onto a two dimensional array of detector elements.
